(19) United States
(12) Patent Application Publication
(10) Pub. No.: US 2026/0176529 A1
(43) Pub. Date: Jun. 25, 2026

(54) ETCHING COMPOSITION, ETCHING METHOD, AND METHOD FOR MANUFACTURING SEMICONDUCTOR SUBSTRATE

(71) Applicant: TOKYO OHKA KOGYO CO., LTD., Kanagawa (JP)

(72) Inventors: Choitsu GO, Kanagawa (JP); Shogo MIYANO, Kanagawa (JP)

(21) Appl. No.: 19/425,187

(22) Filed: Dec. 18, 2025

(30) Foreign Application Priority Data
Dec. 23, 2024 (JP) 2024-226389

(51) Int. Cl. C09K 13/00; H10P 50/64

(52) U.S. Cl. CPC C09K 13/00; H10P 50/642

(57) ABSTRACT

Provided are an etching composition containing (A) an oxidizing agent; (B) a compound capable of releasing fluoride ions or a salt thereof; (C) at least one amine compound selected from the group consisting of an amine compound (c1) having a specific structure, an amine compound (c2) having a specific structure, an amine compound (c3) having a specific structure, piperazine, 1,5,9-triazacyclododecane, 1,4,7-triazacyclononane, cyclen, cyclam, tetraethylenepentamine, and polyethyleneimine, and derivatives thereof, and (D) a corrosion inhibitor, an etching method, and a method for manufacturing a semiconductor substrate.

### BACKGROUND OF THE INVENTION

### 1. Technical Field

### CROSS-REFERENCE TO RELATED APPLICATIONS

The present application claims priority based on Patent Application No. 2024-226389 filed with the Japan Patent Office on Dec. 23, 2024, the entire contents of which are incorporated herein by reference.

The present invention relates to an etching composition, an etching method, and a method for manufacturing a semiconductor substrate.

### 2. Description of the Related Art

In recent years, in semiconductor manufacturing processes, miniaturization of wiring and an increase in the number of laminated layers have been advancing. In such manufacturing processes accompanied by miniaturization and an increase in the number of laminated layers, silicon germanium alloys (SiGe, hereinafter, may be simply referred to as “silicon germanium”) are used. SiGe is obtained by adding germanium to silicon, and has advantages such as higher conductivity, low power consumption, and reduced susceptibility to noise, compared with silicon alone.

For example, in the case of manufacturing an LSI or the like, when introducing a strained Si on Insulator (SOI) structure, an SiGe layer is used as a buffer layer. More specifically, on a silicon substrate, an SiGe layer having a high germanium concentration is laminated as a sacrificial film, and an SiGe layer having a low germanium concentration is further laminated thereon, and a laminate obtained in this manner is employed. As an etching solution used for etching such a laminate, an etching solution using an oxidizing agent such as hydrogen peroxide is used.

With respect to an etching solution for such applications, improvement in the selectivity for the SiGe layer has become an issue; for example, preventing corrosion of an SiGe layer having a low germanium concentration while etching an SiGe layer having a high germanium concentration. Therefore, a technique using peracetic acid for improving selectivity is disclosed (see, for example, Non Patent Literature 1).

### Non Patent Literature

Non Patent Literature 1: S. Lee. et al. Chemical Engineering Journal 475 (2023) 146257

### SUMMARY OF THE INVENTION

However, regarding the etching in the semiconductor manufacturing process using the SiGe described above, a conventional etching solution containing hydrogen peroxide as an oxidizing agent has a problem in that sufficient selectivity of SiGe cannot be ensured. With respect to this problem, although techniques such as using peracetic acid as an oxidizing agent, as in Non Patent Literature 1, have been studied, peracetic acid has poor stability over time, and therefore there are problems in that it is subject to limitations at the time of use and desired selectivity cannot be obtained at the time of use.

The present invention has been made in view of the above circumstances, and an object of the present invention is to provide an etching composition having excellent selectivity for silicon germanium, an etching method, and a method for manufacturing a semiconductor substrate.

As a result of intensive studies to achieve the above object, the present inventors have found that an etching composition accomplishes the above object, the etching composition containing (A) an oxidizing agent; (B) a compound capable of releasing fluoride ions or a salt thereof; (C) at least one amine compound selected from the group consisting of an amine compound (c1) having a specific structure, an amine compound (c2) having a specific structure, an amine compound (c3) having a specific structure, piperazine, 1,5,9-triazacyclododecane, 1,4,7-triazacyclononane, cyclen, cyclam, tetraethylenepentamine, and polyethyleneimine, and derivatives thereof; and (D) a corrosion inhibitor, thereby completing the present invention.

That is, the present invention is as follows.

<1>

An etching composition containing: (A) an oxidizing agent; (B) a compound capable of releasing fluoride ions or a salt thereof; (C) at least one amine compound selected from the group consisting of an amine compound (c1) represented by the following General Formula (c1), an amine compound (c2) represented by the following General Formula (c2), and an amine compound (c3) represented by the following General Formula (c3), piperazine, 1,5,9-triazacyclododecane, 1,4,7-triazacyclononane, cyclen, cyclam, tetraethylenepentamine, and polyethylenimine, and derivatives thereof and (D) a corrosion inhibitor.

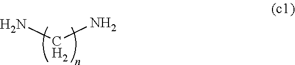

In General Formula (c1), n represents a number of 1 or more.

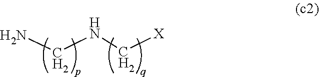

In General Formula (c2), X represents an NH₂ group, an OH group, or an alkyl group, p and q represent numbers of 1 or more, and p and q may be the same or different.

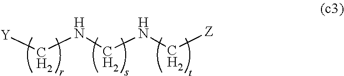

In General Formula (c3), Y and Z each independently represent an NH₂ group, an OH group, or an alkyl group, r, s, and t represent numbers of 1 or more, and r, s, and t may be the same or different.

<2>

The etching composition according to <1>, in which the component (A) includes at least one selected from the group consisting of hydrogen peroxide and an oxo acid.

<3>

The etching composition according to <1> or <2> in which the component (B) is at least one selected from the group consisting of hydrogen fluoride, ammonium fluoride, ammonium hydrogen fluoride, triethanolammonium fluoride, diglycolammonium fluoride, methyldiethanolammonium fluoride, tetramethylammonium fluoride, triethylamine trihydrofluoride, fluoroboric acid, tetrafluoroboric acid, ammonium tetrafluoroborate, fluoroacetic acid, ammonium fluoroacetate, trifluoroacetic acid, fluorosilicic acid, ammonium fluorosilicate, and tetrabutylammonium tetrafluoroborate.

<4>

The etching composition according to <1> or <2>, in which a content of the component (A) is 0.01 to 20 mass %.

<5>

The etching composition according to <1> or <2>, in which a content of the component (B) is 0.01 to 10 mass %.

<6>

The etching composition according to <1> or <2>, in which a content of the component (C) is 0,0005 to 10 mass %.

<7>

The etching composition according to <1> or <2>, further containing water.

<8>

The etching composition according to <7> in which the etching composition has a pH of 6 or less.

<9>

The etching composition according to <1> or <2>, in which the component (D) is at least one selected from the group consisting of a nonionic surfactant, an anionic surfactant, and a cationic surfactant.

<10>

The etching composition according to <1> or <2>, in which the etching composition is an etching composition for selectively etching a layer containing a silicon germanium alloy (SiGe).

<11>

An etching method including etching a laminated substrate including a substrate and a layer provided on the substrate and containing a silicon germanium alloy (SiGe) using an etching composition, in which the etching composition contains (A) an oxidizing agent; (B) a compound capable of releasing fluoride ions or a salt thereof; (C) at least one amine compound selected from the group consisting of an amine compound (c1) represented by the following General Formula (c1), an amine compound (c2) represented by the following General Formula (c2), and an amine compound (c3) represented by the following General Formula (c3), piperazine, 1,5,9-triazacyclododecane, 1,4,7-triazacyclononane, cyclen, cyclam, tetraethylenepentamine, and polyethyleneimine, and derivatives thereof, and (D) a corrosion inhibitor.

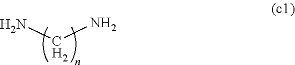

In General Formula (c), n represents a number of 1 or more.

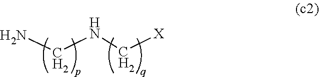

In General Formula (c2), X represents an NH₂ group, an OH group, or an alkyl group, p and q represent numbers of 1 or more, and p and q may be the same or different.

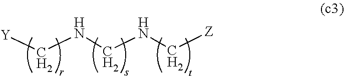

In General Formula (c), Y and Z each independently represent an NH₂ group, an OH group, or an alkyl group, r, s, and t represent numbers of 1 or more, and r, s, and t may be the same or different.

<12>

A method for manufacturing a semiconductor substrate, the method including: etching a laminated substrate including a substrate and a layer provided on the substrate and containing a silicon germanium alloy (SiGe) using an etching composition; and cleaning the etched laminated substrate with a cleaning solution, in which the etching composition contains (A) an oxidizing agent; (B) a compound capable of releasing fluoride ions or a salt thereof; (C) at least one amine compound selected from the group consisting of an amine compound (c1) represented by the following General Formula (c1), an amine compound (c2) represented by the following General Formula (c2), and an amine compound (c3) represented by the following General Formula (c3), piperazine, 1,5,9-triazacyclododecane, 1,4,7-triazacyclononane, cyclen, cyclam, tetraethylenepentamine, and polyethyleneimine, and derivatives thereof; and (D) a corrosion inhibitor.

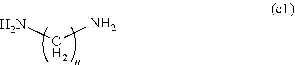

In General Formula (c1), n represents a number of 1 or more.

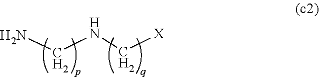

In General Formula (c2), X represents an NH₂ group, an Oil group, or an alkyl group, p and q represent numbers of 1 or more, and p and q may be the same or different.

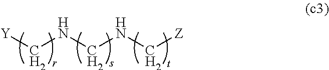

In General Formula (c3), Y and Z each independently represent an NH₂ group, an OH group, or an alkyl group, r, s, and t represent numbers of 1 or more, and r, s, and t may be the same or different.

According to the present invention, it is possible to provide an etching composition having excellent selectivity for silicon germanium, an etching method, and a method for manufacturing a semiconductor substrate.

### DETAILED DESCRIPTION

Hereinafter, an embodiment for carrying out the present invention (hereinafter, simply referred to as “the present embodiment”) will be described in detail. The following present embodiment is an example for describing the present invention, and is not intended to limit the present invention to the following contents. The present invention can be appropriately modified and implemented within the scope of the gist thereof. In addition, the configurations and parameters disclosed in the present specification can be any combination unless otherwise specified. Furthermore, an upper limit and a lower limit of the values disclosed in the present specification can be any combination unless otherwise specified.

In addition, in the present specification, the term “comprise” or “contain” may be replaced with “consist essentially of” and “consist of” as necessary. Further, the expression “A and/or B” means “A, B, or both”, unless otherwise specified.

Note that, in the present specification, the expression “doing something or to do something” may refer to “process” or “step”, “process” may refer to “doing something or to do something” or “step”, and “step” may refer to “doing something or to do something” or “process”. In addition, in the present specification, the term “process” such as “step” may refer to “apparatus or unit that is configured to perform the step”, the term “apparatus” may refer to “mechanism or unit”, and the term “unit” may refer to “unit or apparatus provided for a mechanism, an apparatus, or a system”.

### <Etching Composition>

An etching composition according to the present embodiment contains (A) an oxidizing agent; (B) a compound capable of releasing fluoride ions or a salt thereof, (C) at least one amine compound selected from the group consisting of an amine compound (c1) represented by the following General Formula (c1), an amine compound (c2) represented by the following General Formula (c2), and an amine compound (c3) represented by the following General Formula (c3), piperazine, 1,5,9-triazacyclododecane, 1,4,7-triazacyclononane, cyclen, cyclam, tetraethylenepentamine, and polyethyleneimine, and derivatives thereof; and (D) a corrosion inhibitor.

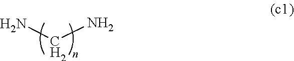

In General Formula (c1), n represents a number of 1 or more.

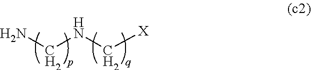

In General Formula (c2), X represents an NH₂ group, an OH group, or an alkyl group, p and q represent numbers of 1 or more, and p and q may be the same or different.

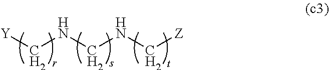

In General Formula (c3), Y and Z each independently represent an NH₂ group, an OH group, or an alkyl group, r, s, and t represent numbers of 1 or more, and r, s, and t may be the same or different.

The etching composition according to the present embodiment has excellent selectivity for SiGe and excellent suppression of damage to silicon. Although the reason for this is not clear, the selectivity between silicon germanium layers having different germanium concentrations can be improved (enhanced selectivity ratio) by using, as the component (C), a specific amine compound in combination with the component (A), which is an oxidizing agent, and the component (B), which serves as a fluoride ion source.

Furthermore, the etching composition according to the present embodiment can have high selectivity for silicon germanium even without containing peracetic acid as an essential component. As described above, an etching composition containing peracetic acid has a problem in stability over time Since peracetic acid is an unstable substance, it decomposes depending on conditions such as various concentrations, temperatures, humidities, and pH. Therefore, when an etching solution that is stored for a long period of time is used, there is a problem in that the desired effect cannot be obtained. As one method for solving such a problem, it is conceivable to prepare peracetic acid from hydrogen peroxide and acetic acid immediately before use to prepare fresh peracetic acid; however, the number of steps increases, and it is not convenient. Furthermore, it is not convenient also in that it takes several days for the concentration of the peracetic acid after preparation to become stable. However, although the etching composition according to the present embodiment is not limited to not containing peracetic acid, since it is not necessary to contain peracetic acid as an essential component, such problems can be avoided (the operations and effects of the present embodiment are not limited thereto).

The etching composition according to the present embodiment is not particularly limited in the etching target and can be used for various etching applications, but the etching composition can be suitably used as an etching composition for selectively etching a layer containing a silicon germanium alloy (SiGe). In addition, the etching composition according to the present embodiment is more suitably used for etching a laminated substrate including a layer containing a silicon germanium alloy (SiGe) and/or a layer containing silicon (Si). Furthermore, the etching composition according to the present embodiment is more suitably used for etching a laminated substrate including a layer containing a silicon germanium alloy (SiGe) and silicon (Si). Furthermore, the etching composition according to the present embodiment is still more suitably used for etching a laminated substrate including a layer containing a first silicon germanium alloy (SiGe), a layer containing a second silicon germanium alloy (SiGe), and a layer containing silicon (Si), in which the first silicon germanium alloy and the second silicon germanium alloy have different germanium content ratios. The etching composition according to the present embodiment has at least excellent selectivity for SiGe.

Furthermore, as a preferred aspect, the etching composition according to the present embodiment can impart not only selectivity for SiGe but also corrosion resistance (damage suppression) to other metals such as silicon by containing a corrosion inhibitor, and therefore, it can be expected that both the selectivity for SiGe and the corrosion resistance to other metals can be maintained at a high level.

Furthermore, as a preferred aspect, the etching composition according to the present embodiment can also be expected to impart an advantage of excellent defoaming properties when it is a liquid.

In the etching of the laminated substrate described above, the advantages of the present embodiment can be effectively utilized.

Hereinafter, the components that may be contained in the etching composition according to the present embodiment and the characteristics thereof will be described.

### ((A) Oxidizing Agent)

The etching composition according to the present embodiment contains (A) an oxidizing agent. Thus, the metal surface can be oxidized and etched. As the oxidizing agent, it is preferable that at least one selected from the group consisting of hydrogen peroxide and an oxo acid is used.

Note that, although specific examples of using the etching composition according to the present embodiment for etching will be described below, a composition containing components other than the component (A) may be prepared in advance, and the component (A) may be mixed with the composition immediately before using the etching composition. For example, a first chemical solution containing the component (B), the component (C), and the component (D) is prepared. Then, before performing etching (preferably immediately before), an etching solution may be prepared by mixing the first chemical solution described above and a second chemical solution containing the component (A), and then used. By adopting such a method of use, for example, the temporal decomposition of the oxidizing agent can be effectively suppressed, and the etching effect can be expected to be further improved.

In addition, with respect to the etching composition according to the present embodiment, when the first chemical solution and the second chemical solution are prepared separately, these chemical solutions can be used as an etching kit provided with the first chemical solution and the second chemical solution. Naturally, the etching kit is not necessarily limited to two kinds of chemical solutions, and, depending on the components, the etching kit may also be provided with chemical solutions other than the first chemical solution and the second chemical solution (e.g., a third chemical solution and a fourth chemical solution).

Specific examples of the oxo acid may include halogen oxo acids (hypochlorous acid, chlorous acid, chloric acid, perchloric acid, hypobromous acid, bromous acid, bromic acid, perbromic acid, hypoiodous acid, iodous acid, iodic acid, periodic acid, and the like), boric acid (H₃BO₃, B(O)₃), silicic acid, nitric acid, and nitrous acid (HNO₂). In addition, the etching composition according to the present embodiment may contain these salts (e.g., sodium salts, potassium salts, calcium salts, barium salts, ammonium salts, and tetraalkylammonium salts).

Examples of the halogen oxo acids may include hypochlorous acid, chlorous acid, chloric acid, perchloric acid, hypobromous acid, bromous acid, bromic acid, perbromic acid, hypoiodous acid, iodous acid, iodic acid, and periodic acid.

Among the oxidizing agents, the oxidizing agent is preferably hydrogen peroxide or a halogen oxo acid; more preferably at least one selected from the group consisting of hydrogen peroxide, hypoiodous acid, iodous acid, iodic acid (HIO₃) and periodic acid; still more preferably at least one selected from the group consisting of hydrogen peroxide, iodic acid, and periodic acid; and even more preferably hydrogen peroxide and/or iodic acid.

In the etching composition according to the present embodiment, above-described oxidizing agents may be used alone or in combination of two or more thereof.

A content of the component (A) in the etching composition according to the present embodiment is not particularly limited, but is preferably 0.01 to 20 mass %. The lower limit of the content is more preferably 0.05 mass % or more, still more preferably 0.08 mass % or more, and even more preferably 0.1 mass % or more. In addition, the upper limit of the content is more preferably 15 mass % or less, still more preferably 13 mass % or less, even more preferably 11 mass % or less, and yet further preferably 10 mass % or less. When the content of the component (A) is within the above range, the selectivity for SiGe, the suppression of damage to silicon, and the defoaming properties can be further improved.

Note that the etching composition according to the present embodiment can achieve sufficient effects even without using an oxidizing agent other than the above hydrogen peroxide, halogen oxo acid, boric acid, silicic acid, nitic acid, and nitrous acid. From this viewpoint, the etching composition according to the present embodiment may not contain an oxidizing agent other than hydrogen peroxide, halogen oxo acid, boric acid, silicic acid, nitric acid, and nitrous acid. From this viewpoint, the etching composition according to the present embodiment can obtain a sufficient effect even without containing other oxidizing agents such as quinones as a main component. For example, a content of quinones in the etching composition according to the present embodiment is preferably less than 0.1 mass %, more preferably less than 0.05 mass %, and still more preferably less than 0.001 mass %, and it is preferable that the etching composition does not contain quinones.

In addition, as described above, the etching composition according to the present embodiment can achieve sufficient effects even without containing peracetic acid as a main component From this viewpoint, a content of peracetic acid in the etching composition according to the present embodiment is preferably less than 0.1 mass %, more preferably less than 0.05 mass %, and still more preferably less than 0.001 mass %, and it is more preferable that the etching composition does not contain peracetic acid.

From a similar viewpoint, a content of hydroxylamine in the etching composition according to the present embodiment is preferably less than 0.1 mass %, more preferably less than 0.05 mass %, and still more preferably less than 0.001 mass %, and it is more preferable that the etching composition does not contain hydroxylamine.

From the viewpoint described above, it is more preferable that the etching composition according to the present embodiment may not contain quinones, peracetic acid, and hydroxylamine.

### ((B) Compound Capable of Releasing Fluoride Ions and Salt Thereof)

The etching composition according to the present embodiment contains (B) a compound capable of releasing fluoride ions and a salt thereof (hereinafter, these may be collectively referred to as “fluorine-based compounds”). Specific examples of the fluorine-based compound are not particularly limited, but are preferably at least one selected from the group consisting of hydrogen fluoride (HF), hexafluorosilicic acid, ammonium fluoride, ammonium hydrogen fluoride, triethanolammonium fluoride, diglycolammonium fluoride, methyldiethanolammonium fluoride, tetramethylammonium fluoride (TMAF), triethylamine trihydrofluoride, fluoroboric acid, tetrafluoroboric acid, ammonium tetrafluoroborate, fluoroacetic acid, ammonium fluoroacetate, trifluoroacetic acid, fluorosilicic acid, ammonium fluorosilicate, and tetrabutylammonium, tetrafluoroborate. Among them, the fluorine-based compound is more preferably at least one selected from the group consisting of hydrogen fluoride (HF), hexafluorosilicic acid, ammonium fluoride, ammonium hydrogen fluoride, and tetramethylammonium fluoride (TMAF), and still more preferably at least one selected from the group consisting of hydrogen fluoride, ammonium fluoride, ammonium hydrogen fluoride, and tetramethylammonium fluoride (TMAF).

Note that, in the case of hydrogen fluoride, a hydrogen fluoride solution (an aqueous solution of hydrogen fluoride, aqueous hydrogen fluoride, or aqueous HF) may be added when producing the etching composition according to the present embodiment. In addition, the salt of the compound capable of releasing fluoride ions is not particularly limited, and examples thereof may include sodium salts, potassium salts, ammonium salts, and alkylammonium salts (e.g., tetramethylammonium salts).

The components (B) may be used alone or in combination of two or more thereof.

A content of the component (B) in the etching composition according to the present embodiment is not particularly limited, but is preferably 0.01 to 10 mass %. The lower limit of the content is more preferably 0.02 mass % or more, still more preferably 0.03 mass % or more, and even more preferably 0.04 mass % or more. In addition, the upper limit of the content is more preferably 5 mass % or less, still more preferably 3 mass % or less, even more preferably 1 mass % or less, and yet further preferably 0.8 mass % or less. When the content of the component (B) is within the above range, the selectivity for SiGe, the suppression of damage to silicon, and the defoaming properties can be further improved.

Note that the etching composition according to the present embodiment can achieve sufficient effects even without containing a compound capable of releasing fluoride ions other than the above hydrogen fluoride (IF), hexafluorosilicic acid, ammonium fluoride, ammonium hydrogen fluoride, and tetramethylammonium fluoride (TMAF).

### ((C) Amine Compound)

The etching composition according to the present embodiment contains (C) at least one amine compound selected from the group consisting of an amine compound (c1) represented by General Formula (c1), an anine compound (c2) represented by General Formula (c2), an amine compound (c3) represented by General Formula (c3f), piperazine, 1,5,9-triazacyclododecane, 1,4,7-triazacyclononane, cyclen, cyclam, tetraethylenepentamine, and polyethyleneimine, and derivatives thereof.

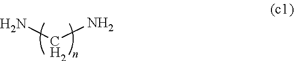

In General Formula (c1) n represents a number of 1 or more.

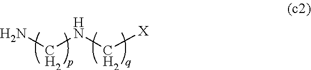

In General Formula (c2) X represents an NH₂ group, an OH group, or an alkyl group, p and q represent numbers of 1 or more, and p and q may be the same or different.

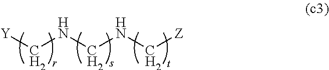

In General Formula (c3), Y and Z each independently represent an NH₂ group, an OH group, or an alkyl group, r, s, and t represent numbers of 1 or more, and r, s, and t may be the same or different.

It is considered that, by containing the component (C), the etching composition according to the present embodiment can particularly increase the etching rate of SiGe having a high germanium concentration, and as a result, can improve the selectivity for SiGe. In addition, although the etching composition according to the present embodiment is not necessarily restricted from containing peracetic acid, the selectivity for silicon germanium can be increased to a practical level even without the use of peracetic acid.

Furthermore, it is considered that the amine compound (C), by exhibiting chelating ability, can chelate-coordinate with metals eluted during etching, thereby suppressing the self-decomposition reaction of the oxidizing agent caused by the metals and improving the recyclability of the chemical solution. As a result, both the etching performance for SiGe having a high germanium concentration and the corrosion resistance of SiGe having a low germanium concentration can be maintained at a high level.

With respect to the component (C), it is considered that, due to the operations and effects described above, the etching composition according to the present embodiment can exhibit high selectivity for silicon germanium through interactions among the components (however, the operations and effects of the present embodiment are not limited thereto).

In the following General Formula (c1) of the amine compound (c1), n is preferably 1 or more and 15 or less. The upper limit of n is more preferably 14 or less, still more preferably 13 or less, and even more preferably 12 or less. The lower limit of n is more preferably 2 or more. Within such a range, the effects of the present embodiment can be further improved.

Specific examples of the amine compound (c1) are preferably at least one selected from the group consisting of ethylenediamine (EDA), 1,3-propanediamine, 1,4-butanediamine, 1,5-pentanediamine, 1,6-hexanediamine, 1,7-heptanediamine, 1,8-octanediamine, 1,9-nonanediamine. 1,10-decanediamine, 1,11-undecanediamine, and 1,12-dodecanediamine.

X in General Formula (c2) of the amine compound (c2) is preferably an NH 2 group, an OH group, or an alkyl group having 1 to 4 carbon atoms. The alkyl group is preferably a methyl group, an ethyl group, a propyl group, or a butyl group.

It is preferable that p and q in General Formula (c2) are each independently 1 or more and 4 or less. The upper limits of p and q are each independently preferably 3 or less, and more preferably 2 or less.

Specific examples of the amine compound (c2) are preferably at least one selected from the group consisting of N-(2-aminoethyl)ethanolamine (ABEEA), diethylenetriamine (DETA), N-methylethylenediamine, and N-ethylethylenediamine.

It is preferable that Y and Z in General Formula (c3) of the amine compound (03) are each independently an NH₂ group, an OH group, or an alkyl group having 1 to 4 carbon atoms. The alkyl group is preferably a methyl group, an ethyl group, a propyl group, or a butyl group.

It is preferable that r, s, and t in General Formula (c3) are each independently 1 or more and 5 or less. It is more preferable that the upper limits of r, s, and t are each independently 4 or less. In addition, it is more preferable that the lower limits of r, s, and t are each independently 2 or more.

Specific examples of the amine compound (c3) are preferably at least one selected from the group consisting of N,N′-bis(2-hydroxyethyl)ethylenediamine, 3,3′-diaminodipropylamine, triethylenetetramine, and N,N′-diethylethylenediamine.

Polyethyleneimine (PET) is a polymer in which amines are linked by ethylene chains. Specific examples of polyethyleneimine are preferably at least one selected from the group consisting of branched types, linear types, and dendrimer types, and more preferably the branched type.

A weight average molecular weight (M_{w}) of polyethyleneimine is not particularly limited, but is preferably 200 to 30,000. The upper limit of the molecular weight is more preferably 20,000 or less, still more preferably 10,000 or less, even more preferably 5,000 or less, and yet further preferably 2,000 or less. The weight average molecular weight can be measured by gel permeation chromatography (GPC).

In addition, the polyethyleneimine is preferably a homopolymer.

The component (C) may also be contained as a derivative of each of the above-described amine compounds. Examples of the derivative may include 2-methylpiperazine, 1,2-diaminopropane, and N-acetylethylenediamine.

The components (C) may be used alone or in combination of two or more thereof.

A content of the component (C) in the etching composition according to the present embodiment is not particularly limited, but is preferably 0,0005 to 10 mass %. The lower limit of the content is more preferably 0.001 mass % or more, still more preferably 0.005 mass % or more, and even more preferably 0.008 mass % or more. In addition, the upper limit of the content is more preferably 8 mass % or less, still more preferably 6 mass % or less, even more preferably 4 mass % or less, and yet further preferably 3 mass % or less. When the content of the component (C) is within the above range, the additive effects of the component (C) described above can be further improved. Furthermore, the selectivity for SiGe and the suppression of damage to silicon can be further improved.

### ((D) Corrosion Inhibitor)

It is preferable that the etching composition according to the present embodiment contains (D) a corrosion inhibitor as necessary in consideration of the metal species of the laminated substrate to be etched. The etching composition according to the present embodiment can maintain a high level of selectivity for silicon germanium without reducing the corrosion resistance of metals other than SiGe to be etched. Although such a corrosion inhibitor is not particularly limited, the corrosion inhibitor is preferably at least one selected from the group consisting of a nonionic surfactant, an anionic surfactant, and a cationic surfactant (hereinafter, these surfactants may be collectively referred to as “first corrosion inhibitor”). More preferably, the corrosion inhibitor is at least one selected from the group consisting of a nonionic surfactant and an anionic surfactant. These corrosion inhibitors are preferably those other than the amine compounds (C) described above.

Examples of the nonionic surfactant may include a polyalkylene oxide alkyl phenyl ether-based surfactant, a polyalkylene oxide alkyl ether-based surfactant, a block polymer-based surfactant composed of polyethylene oxide and polypropylene oxide, a polyoxyalkylene distyrenated phenyl ether-based surfactant, a polyalkylene tribenzyl phenyl ether-based surfactant, and an acetylene polyalkylene oxide-based surfactant. Commercially available products can also be used as the nonionic surfactant. Examples of the commercially available products may include “ACETYLENOL E40”, “ACETYLENOL E60”, and “ACETYLENOL E100” manufactured by Kawaken Fine Chemicals Co., Ltd.; “TERGITOL (trademark) TMN6” and “TERGITOL (trademark) TMN10” manufactured by Dow Inc.; “Softanol (trademark) 90” manufactured by NIPPON SHOKUBAI CO., LTD.; and “TriTon (trademark) X-100” manufactured by Sigma-Aldrich.

Examples of the anionic surfactant may include dodecylbenzenesulfonic acid (DBSA), alkylsulfonic acids, alkylnaphthalenesulfonic acids, alkyl diphenyl ether sulfonic acids, fatty acid amidosulfonic acids, polyoxyethylene alkyl ether carboxylic acids, polyoxyethylene alkyl ether acetic acids, polyoxyethylene alkyl ether propionic acids, and alkylphosphonic acids.

Examples of the cationic surfactant may include an alkylpyridinium-based surfactant.

The etching composition according to the present embodiment may further contain another corrosion inhibitor (a second corrosion inhibitor) in addition to the above-described corrosion inhibitor (the first corrosion inhibitor). Examples of the second corrosion inhibitor may include other corrosion inhibitors that prevent corrosion of metals other than SiGe. Examples of the second corrosion inhibitor may include polyvinylpyrrolidone (PVP), a copolymer of vinylpyrrolidone and vinyl acetate, and polyethylene glycol. For example, PVP and the like can impart a corrosion-prevention effect to silicon oxide, silicon nitride, and the like, Even when the etching composition according to the present embodiment contains a corrosion inhibitor for silicon oxide or silicon nitride, the etching composition can impart a corrosion-prevention effect to these materials while maintaining high selectivity for SiGe.

The corrosion inhibitors may be used alone or in combination of two or more thereof.

A content of the component (D) in the etching composition according to the present embodiment is not particularly limited, but is preferably 0.0001 to 1 mass %. The lower limit of the content is more preferably 0.0002 mass % or more, still more preferably 0.0003 mass % or more, and even more preferably 0.0005 mass % or more. In addition, the upper limit of the content is more preferably 0.8 mass % or less, still more preferably 0.7 mass % or less, even more preferably 0.6 mass % or less, and yet further preferably 0.5 mass % or less.

### (pH Adjuster)

The etching composition according to the present embodiment may contain a pH adjuster in order to adjust the pH to a desired value. As the pH adjuster, inorganic acids, organic acids, organic basic compounds, and inorganic basic compounds can be appropriately used. For example, sulfuric acid, sulfurous acid, phosphoric acid, and the like are preferable.

The pH adjusters may be used alone or in combination of two or more thereof.

A content of the pH adjuster in the etching composition according to the present embodiment is not particularly limited, but may be 0.01 to 1 mass %. The lower limit of the content may be 0.05 mass % or more, 0.1 mass % or more, or 0.15 mass % or more. In addition, the upper limit of the content may be 0.8 mass % or less, 0.6 mass % or less, 0.5 mass % or less, or 0.3 mass % or less.

### (Solvent)

The etching composition according to the present embodiment may contain a solvent. For example, the solvent preferably contains water. The etching composition according to the present embodiment can be suitably used as an aqueous etching composition.

A content of water in the etching composition according to the present embodiment is not particularly limited, but is preferably 1 to 99 mass %. The lower limit of the content is more preferably 25 mass % or more, still more preferably 35 mass % or more, even more preferably 45 mass % or more, yet even more preferably 50 mass % or more, further preferably 55 mass % or more, yet further preferably 60 mass % or more, even further preferably 80 mass % or more, and most preferably 85 mass % or more. In addition, the upper limit of the content is more preferably 99 mass % or less. When the content of water is within the above range, the other components can be uniformly and stably dissolved, and the desired effects can be maintained while imparting water solubility as an aqueous etching composition.

In addition, the etching composition according to the present embodiment may contain an organic solvent. Specific examples of the organic solvent may include, but are not limited to, at least one selected from the group consisting of an alcohol-based solvent, a glycol ether-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an acetate-based solvent, a pyrrolidone-based solvent, and a urea-based solvent. Among them, at least one selected from the group consisting of an alcohol-based solvent, a glycol ether-based solvent, a sulfoxide-based solvent, a sulfone-based solvent, an amide-based solvent, an imidazolidinone-based solvent, a nitrile-based solvent, a ketone-based solvent, an ether-based solvent, a pyrrolidone-based solvent, and a urea-based solvent is preferable. In addition, when the etching composition according to the present embodiment contains an organic solvent, it is preferable to use a water-soluble organic solvent from the viewpoint of imparting water solubility.

### (Impurities and the Like)

The etching solution according to the present embodiment may contain, for example, a metal impurity containing at least one selected from the group consisting of Fe atoms, Cr atoms, Ni atoms, Zn atoms, Ca atoms, and Pb atoms.

The total content of the metal atoms in the etching solution according to the present embodiment is preferably 100 mass ppt or less with respect to the total mass of the etching solution. The lower limit value of the total content of the metal atoms is preferably as low as possible, and is, for example, 0.001 mass ppt or more. The total content of the metal atoms is, for example, 0.001 mass ppt to 100 mass ppt. By setting the total content of the metal atoms to be equal to or less than the above-described preferred upper limit value, it is considered that the defect suppressing property and the residue suppressing property of the etching solution are improved. It is considered that when the total content of the metal atoms is set to be equal to or more than the above-described preferred lower limit value, the metal atoms hardly exist in the system separately, and the manufacturing yield of the entire target to be cleaned is hardly adversely affected.

The content of the metal impurities can be adjusted, for example, by a purification treatment such as filtering. The purification treatment such as filtering may be performed on a part or all of the raw materials before preparing the etching solution or may be performed after the etching solution is prepared.

The etching solution according to the present embodiment may contain, for example, impurities derived from organic substances (organic impurities) The total content of the organic impurities in the etching solution according to the present embodiment is preferably 5,000 mass ppm or less. The lower limit of the content of the organic impurities is preferably as low as possible, and is, for example, 0.1 mass ppm or more. Examples of the total content of the organic impurities may include 0.1 mass ppm to 5,000 mass ppm.

The etching solution according to the present embodiment may contain, for example, targets to be counted having a size countable by a light scattering type in-liquid particle counter. The size of the target to be counted is, for example, 0.04 μm or more. The number of the targets to be counted in the etching solution according to the present embodiment per 1 mL of the etching solution is, for example, 1,000 or less, and the lower limit value is, for example, 0.1 or more. It is considered that, when the number of targets to be counted in the etching solution is within the range described above, the effect of preventing metal corrosion, the effect of reducing defects, and the like by the etching solution are improved (however, the operations and effects of the present embodiment are not limited thereto).

The organic impurities and/or the targets to be counted described above may be added to the etching solution or may be inevitably mixed into the etching solution in a manufacturing step of the etching solution. Examples of cases where the organic impurities are inevitably mixed in the manufacturing step of the etching solution may include, but are not limited to, a case where the organic impurities are included in a raw material (e.g., an organic solvent) used for manufacturing the etching solution, and a case where the organic impurities are mixed from an external environment in the manufacturing step of the etching solution (e.g., contamination).

When the targets to be counted are added to the etching solution, an abundance ratio may be adjusted for each specific size considering surface roughness and the like of the object to be cleaned.

pH

A pH of the etching composition according to the present embodiment is not particularly limited, but is preferably 6 or less. The lower limit of the pH is preferably 1 or more, and more preferably 2 or more. The upper limit of the pH is more preferably 4.5 or less. For example, a preferred example of a combination of the upper limit and the lower limit of pH is 1 or more and 6 or less. When the pH is within the above range, the selectivity for SiGe, the suppression of damage to silicon, and the defoaming properties can be further improved. The pH can be controlled to have a desired pH by adding the above-described pH adjuster or the like.

### <Etching Method>

The etching composition according to the present embodiment can be suitably used for etching of the laminated substrate described above. That is, examples of a preferred aspect of the etching method according to the present embodiment may include an etching method including etching a laminated substrate including a substrate and a layer provided on the substrate and containing a silicon germanium alloy (SiGe) using an etching composition, in which the etching composition contains (A) an oxidizing agent; (B) a compound capable of releasing fluoride ions or a salt thereof; (C) at least one amine compound selected from the group consisting of an amine compound (c) represented by General Formula (c1), an amine compound (c2) represented by General Formula (c2), and an amine compound (c3) represented by General Formula (c3), piperazine, 1,5,9-triazacyclododecane, 1,4,7-triazacyclononane, cyclen, cyclam, tetraethylenepentamine, and polyethyleneimine, and derivatives thereof, and (D) a corrosion inhibitor. For the etching composition used in the etching method according to the present embodiment, the contents of the etching composition described above can be appropriately adopted. For the laminated substrate to be treated in the etching method according to the present embodiment, the configuration and other contents of the laminated substrate described in the etching composition can be appropriately adopted.

Note that, for the etching composition used in the etching method according to the present embodiment, it is preferable that, before the above-described etching step, a preparation step of preparing the etching composition is further included, the preparation step including mixing a first chemical solution containing the component (B), the component (C), and the component (D) with a second chemical solution containing the component (A). By preparing the first chemical solution and the second chemical solution in advance and mixing them before the etching step (preferably immediately before the etching step) to prepare the etching composition, the etching composition can be used in a state in which the temporal decomposition of the oxidizing agent, which is the component (A), is effectively suppressed, thereby further improving the etching effect.

The first chemical solution may further contain other components in addition to the component (B), the component (C), and the component (D), as long as they are components other than the component (A). For example, the first chemical solution may contain at least one selected from the group consisting of a corrosion inhibitor, a pH adjuster, and a solvent, as described above.

The second chemical solution may further contain other components in addition to the oxidizing agent, which is the component (A). For example, the second chemical solution may further contain the solvent described above. From the viewpoint of suppressing temporal decomposition of the oxidizing agent, it is preferable that the second chemical solution contain only an oxidizing agent and a solvent (e.g., water and/or an organic solvent). For example, it is preferable to use aqueous hydrogen peroxide as the second chemical solution.

Furthermore, another chemical solution (e.g., a third chemical solution or a fourth chemical solution) other than the first chemical solution and the second chemical solution may also be prepared, and the first chemical solution, the second chemical solution, and the other chemical solution may be mixed before the treatment step to prepare the processing solution, Examples of the other chemical solutions (e.g., a third chemical solution and a fourth chemical solution) may include chemical solutions containing, for example, other components such as a pH adjuster or a buffer described above and a solvent (e.g., water and/or an organic solvent).

As described above, when the first chemical solution and the second chemical solution are prepared separately, these chemical solutions can be used as an etching kit. That is, the etching method can further include, before the above-described treatment step, a step of preparing a processing solution kit containing a first chemical solution and a second chemical solution, and a step of preparing a processing solution by mixing the first chemical solution and the second chemical solution.

The treatment conditions of the etching method according to the present embodiment are not particularly limited, and appropriate conditions can be selected in consideration of the material and configuration of the laminated substrate to be etched and the level of the scale-up process. As the etching method, for example, an immersion method, a spray method, or a liquid-flooding method can be employed.

For example, the treatment temperature in the etching step is not particularly limited and may be 10 to 80° C. The lower limit of the treatment temperature may be 15° C. or higher or 20° C. or higher. In addition, the upper limit of the treatment temperature may be 70° C. or lower, 60° C. or lower, 50° C. or lower, 40° C. or lower, or 30° C. or lower.

For example, the treatment time in the etching step is not particularly limited and may be 10 seconds to 10 hours. The lower limit of the treatment time may be 30 seconds or more, 1 minute or more, 5 minutes or more, 10 minutes or more, 15 minutes or more, 20 minutes or more, 25 minutes or more, or 30 minutes or more. In addition, the upper limit of the treatment time may be 8 hours or less, 5 hours or less, 3 hours or less, 2 hours or less, or 1 hour or less.

An etching composition containing a surfactant tends to generate undesirable foaming when being filled into a tank, and the foaming is likely to cause malfunction of a water-level detection unit (e.g. a water-level meter or a level gauge) provided in the tank. However, since the etching composition of the present embodiment has excellent defoaming properties, such problems can be effectively suppressed.

The etching method according to the present embodiment may include a cleaning step of cleaning the laminated substrate before the etching step. The cleaning step can be performed using a known cleaning solution. Examples of the cleaning solution may include, for example, aqueous hydrogen fluoride (aqueous HF). The cleaning can be performed by bringing the cleaning solution into contact with the laminated substrate by a spin coating method, a dip method, a spray method, a paddle method, or the like. The cleaning can be performed at atmospheric pressure and at room temperature (about 15 to 30° C.). Examples of the contact time between the cleaning solution and the laminated substrate may include 10 to 180 seconds, 20 to 120 seconds, and 30 to 60 seconds.

It is preferable that the etching method according to the present embodiment includes a cleaning step and/or a drying step after the etching step. The cleaning step after the etching can be performed using a known cleaning solution. Examples of the cleaning solution may include water. The cleaning can be performed by bringing the cleaning solution into contact with the laminated substrate by a spin coating method, a dip method, a spray method, a paddle method, or the like. The cleaning can be performed at atmospheric pressure and at room temperature (about 15 to 30° C.). Examples of the contact time between the cleaning solution and the laminated substrate may include 10 to 180 seconds, 20 to 120 seconds, and 30 to 60 seconds. The drying step can employ a drying method such as natural drying or nitrogen blow drying.

### <Method for Manufacturing, Semiconductor Substrate>

The etching composition and the etching method according to the present embodiment can be suitably used in a method for manufacturing a semiconductor substrate. Examples of a preferred aspect of the method for manufacturing a semiconductor substrate according to the present embodiment may include a method for manufacturing a semiconductor substrate, the method including: etching a laminated substrate including a substrate and a layer provided on the substrate and containing a silicon germanium alloy (SiGe) using an etching composition; and cleaning the etched laminated substrate with a cleaning solution, in which the etching composition contains (A) an oxidizing agent; (B) a compound capable of releasing fluoride ions or a salt thereof; (C) at least one amine compound selected from the group consisting of an amine compound (c1) represented by General Formula (c1), an amine compound (c2) represented by General Formula (c2), and an amine compound (c3) represented by General Formula (c3), piperazine, 1,5,9-triazacyclododecane, 1,4,7-triazacyclononane, cyclen, cyclam, tetraethylenepentamine, and polyethyleneimine, and derivatives thereof and (D) a corrosion inhibitor. For the etching composition used in the method for manufacturing a semiconductor substrate according to the present embodiment, the contents of the etching composition described above can be appropriately adopted. For the laminated substrate used in the method for manufacturing a semiconductor substrate according to the present embodiment, the configuration and other contents of the laminated substrate described in the etching composition can be appropriately adopted.

### EXAMPLES

The present invention is described in more detail with reference to the following examples and comparative examples, but the present invention is not limited to the following examples at all.

### <Component Names and Abbreviations>

Note that the component names and abbreviations shown in the tables are as follows.

### (Amine Compound)

EDA: Ethylenediamine (a compound corresponding to General Formula (c1))
NH₄OH: Ammonium hydroxide
TMAH: Tetramethylammonium hydroxide
MEA: Monoethanolamine
AEEA: N-(2-Aminoethyl)ethanolamine (an amine compound having the structure represented by the formula below, corresponding to General Formula (c2))

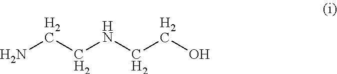

DETA: Diethylenetriamine (a compound corresponding to General Formula (c2))
Cyclen: Cyclen (a cyclic amine compound having the structure represented by the formula below)
Piperazine: Piperazine

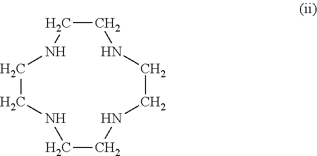 [SMILES: C1CNCCNCCNCCN1]

A1: N,N′Bis(2-hydroxyethyl)ethylenediamine (an amine compound having the structure represented by the formula below, corresponding to General Formula (c3))

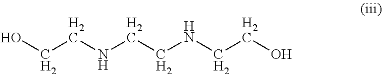

A2: 3,3′-Diaminodipropylamine (an amine compound having the structure represented by the formula below, corresponding to General Formula (c3))

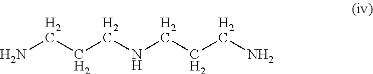

A3: Triethylenetetramine (an amine compound having the structure represented by the formula below, corresponding to General Formula (c3))

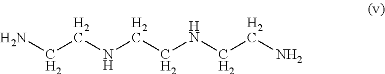

A4: Tetraethylenepentamine (an amine compound having the structure represented by the formula below, corresponding to General Formula (c3))

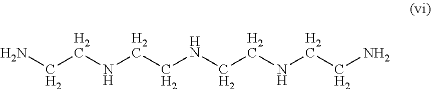

Lupasol PR8515: Polyethyleneimine (branched polyethyleneimine, manufactured by BASF SE, “Lupasol PR8515”, weight average molecular weight (M_{w}) 2,000)
EPOMIN SP-003: Polyethyleneimine (branched polyethyleneimine, manufactured by NIPPON SHOKUBAI CO., LTD., “EPOMIN SP-003”, weight average molecular weight (M_{w}) 300)
EPOMIN SP-006: Polyethyleneimine (branched polyethyleneimine, manufactured by NIPPON SHOKUBAI CO. LTD., “EPOMIN SP-006”, weight average molecular weight (M_{w}) 600)
EPOMIN SP-012: Polyethyleneimine (branched polyethyleneimine, manufactured by NIPPON SHOKUBAI CO., LTD., “EPOMIN SP-012” weight average molecular weight (M_{w}) 1,200)
EPOMIN SP-018: Polyethyleneimine (branched polyethyleneimine, manufactured by NIPPON SHOKUBAI CO, LTD., “EPOMIN SP-018”, weight average molecular weight (M_{w}) 1,800)

### (Corrosion Inhibitor)

E40: Acetylenic glycol manufactured by Kawaken Fine Chemicals Co., Ltd., having the trade name “ACETYLENOL E40”, having the structure represented by the following formula, and serving as a nonionic surfactant

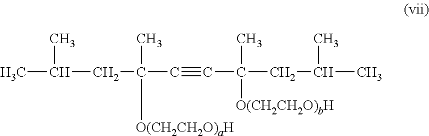

In the formula, a and b each independently represent a number, and a+b is 4.
E100: Acetylenic glycol manufactured by Kawaken Fine Chemicals Co., Ltd., having the trade name “ACETYLENOL E 100”, having the structure represented by the following formula, and serving as a nonionic surfactant

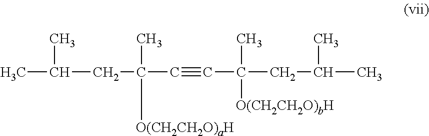

In the formula, a and b each independently represent a number, and a+b is 10.
TMN6: Surfactant manufactured by Dow Inc., having the trade name “TERGITOL (trademark) TMN6”, having the structure represented by the following formula, and serving as a nonionic surfactant

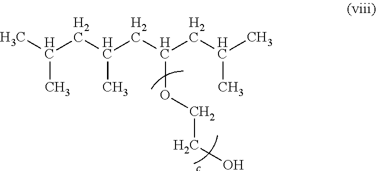

In the formula, c represents a number and has an average value of 8.
TMN10: Nonionic surfactant manufactured by Dow Inc., having the trade name “TERGITOL (trademark) TMN10” (product name “TERGITOL (trademark) TMN-10”), and having the structure represented by the following formula

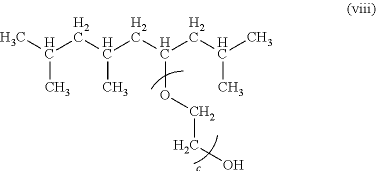

In the formula, c represents a number and has an average value of 11.
Softanol 90: Nonionic surfactant manufactured by NIPPON SHOKUBAI CO., LTD., having the trade name “Softanol (trademark) 90”, having the structure represented by the following formula, and having a Griffin's calculated HLB value of 13.3. Note that the Griffin hydrophile-lipophile balance (HLB) value is one of the indices representing the degree of affinity of a surfactant for water and oil (an organic compound insoluble in water), and can be determined by 20×the total formula weight of the hydrophilic portion/the molecular weight.

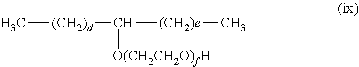

In the formula, f is 9 and d+e is 9 to 11.
Triton X-100: Polyethylene glycol octylphenyl ether manufactured by Sigma-Aldrich, having the trade name “TriTon (trademark) X-100”, having the structure represented by the following formula, and serving as a nonionic surfactant

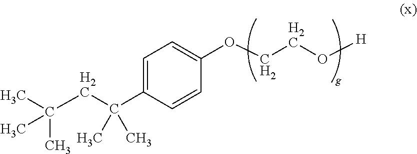

In the formula, g is 9 to 10
DBSA: Dodecylbenzenesulfonic acid (an anionic surfactant)
PVP: Polyvinylpyrrolidone

### 1. Test 1

### Examples 1 to 47 and Comparative Examples 1 to 6

Etching solutions having the compositions shown in the respective tables were prepared. For example, the etching solution of Example 1 contains 2 mass % hydrogen peroxide (H₂O₂), 0.1 mass % hydrogen fluoride (HF), 0.08 mass % EDA as an amine compound, 0.1 mass % E40 as a corrosion inhibitor, and the balance of water (deionized water, DIW).

<Measurement of pH>

The pH of the etching solution was measured using a pH/ORP meter (portable pH meter “ORION STAR A324”, manufactured by Thermo Fisher Scientific Inc.) under a temperature condition of 25° C.

### <Measurement of Etching Rate>

Test samples (wafer coupons) were obtained by cutting, in plain view, a laminate (blanket wafer) on which an SiGe₄₀ layer (a silicon germanium alloy having a mass ratio of Si60:Ge40 and a film thickness of 20 nm) was formed and a laminate (blanket wafer) on which an SiGe₂₀ layer (a silicon germanium alloy having a mass ratio of Si80:Ge20 and a film thickness of 20 nm) was formed, into pieces of 2 cm×2 cm.

Then, as a pretreatment, the sample was immersed in 0.5 mass % aqueous hydrogen fluoride (aqueous HF) for 1 minute, and then washed and dried by nitrogen blow.

Thereafter, 100 mL of each etching solution of each of the Examples and Comparative Examples was placed in a 200-mL cup. Each sample was then introduced into the cup and treated by stirring at 300 rpm at a treatment temperature of 25° C. Note that the treatment time was 0.5 to 3 minutes for the laminate including the SiGe₄₀ layer, and 10 minutes for the laminate including the SiGe₂₀ layer. After the treatment, each sample was taken out of the etching solution, washed with water at room temperature for 30 seconds, and dried by nitrogen blow.

Then, for SiGe₄₀ and SiGe₂₀, the film reduction after the treatment was evaluated by measuring the etching rate (ER, Å/min) after the treatment relative to that before the treatment. A lower etching rate of the SiGe layer indicates that damage to the SiGe layer was more effectively suppressed. Note that the film thickness before the treatment and the film thickness after the treatment were measured by the following methods.
The film thicknesses of SiGe₄₀ and SiGe₂₀ were measured using a scanning X-ray fluorescence analyzer (“ZSX Primus IV”, manufactured by Rigaku Corporation).

### <Evaluation of Selectivity>

The selectivity of SiGe₄₀ to SiGe₂₀ (SiGe₄₀/SiGe₂₀) was determined by dividing the etching rate of SiGe₄₀ by the etching rate of SiGe₂₀. A larger value indicates better selectivity. The selectivity was evaluated according to the following criteria.
A: The selectivity value was 30 or more
B: The selectivity value was less than 30.

### <Evaluation of Defoaming Properties>

In a 50-mL graduated cylinder, 25 mL of each etching solution of each of the Examples was placed, and shaking by hand was performed for 30 seconds. The shaking was performed under identical conditions among all the Examples and Comparative Examples. After the shaking, the time required for the foam to disappear was measured, and a shorter time was regarded as indicating better defoaming properties. The defoaming properties were evaluated according to the following criteria.
A: The foam disappeared in less than 5 minutes.
B: The foam disappeared in 5 minutes or more.

As a result, the evaluation was “A” in all of the Examples.

Table 1 shows the compositions and pH values of the etching solutions of Examples 1 to 10 and Comparative Examples 1 to 6, and Table 2 shows the evaluation results thereof. Table 3 shows the compositions and pH values of the etching solutions of Examples 11 to 21, and Table 4 shows the evaluation results thereof. Table 5 shows the compositions and pH values of the etching solutions of Examples 22 to 36, and Table 6 shows the evaluation results thereof. Table 7 shows the compositions and pH values of the etching solutions of Examples 37 to 47, and Table 8 shows the evaluation results thereof.

TABLE 1

| | Oxidizing agent | | Fluorine-based compound | | Amine compound | | Corrosion inhibitor | | | |
|---|---|---|---|---|---|---|---|---|---|---|
| | | Content | | Content | | Content | | Content | Solvent | |
| | Kind | (mass %) | Kind | (mass %) | Kind | (mass %) | Kind | (mass %) | Water | pH |
| Comparative | Hydrogen | 2 | Hydrogen | 0.1 | — | — | — | — | Balance | 3 |
| Example 1 | peroxide | | fluoride | | | | | | | |
| Comparative | Hydrogen | 2 | Hydrogen | 0.1 | EDA | 0.05 | — | — | Balance | 3 |
| Example 2 | peroxide | | fluoride | | | | | | | |
| Comparative | Hydrogen | 2 | Hydrogen | 0.1 | — | — | E40 | 0.1 | Balance | 3 |
| Example 3 | peroxide | | fluoride | | | | | | | |
| Example 1 | Hydrogen | 2 | Hydrogen | 0.1 | EDA | 0.08 | E40 | 0.1 | Balance | 4 |
| | peroxide | | fluoride | | | | | | | |
| Comparative | Hydrogen | 2 | Hydrogen | 0.1 | NH₄OH | 0.08 | E40 | 0.1 | Balance | 4 |
| Example 4 | peroxide | | fluoride | | | | | | | |
| Comparative | Hydrogen | 2 | Hydrogen | 0.1 | TMAH | 0.1 | E40 | 0.1 | Balance | 4 |
| Example 5 | peroxide | | fluoride | | | | | | | |
| Comparative | Hydrogen | 2 | Hydrogen | 0.1 | MEA | 0.1 | E40 | 0.1 | Balance | 4 |
| Example 6 | peroxide | | fluoride | | | | | | | |
| Example 2 | Hydrogen | 2 | Hydrogen | 0.1 | ABEA | 0.1 | E40 | 0.1 | Balance | 4 |
| | peroxide | | fluoride | | | | | | | |
| Example 3 | Hydrogen | 2 | Hydrogen | 0.1 | DETA | 0.1 | E40 | 0.1 | Balance | 4 |
| | peroxide | | fluoride | | | | | | | |
| Example 4 | Hydrogen | 2 | Hydrogen | 0.1 | Cyclen | 0.08 | E40 | 0.1 | Balance | 3 |
| | peroxide | | fluoride | | | | | | | |
| Example 5 | Hydrogen | 2 | Hydrogen | 0.1 | Piperazine | 0.1 | E40 | 0.1 | Balance | 3 |
| | peroxide | | fluoride | | | | | | | |
| Example 6 | Hydrogen | 2 | Hydrogen | 0.1 | A1 | 0.1 | E40 | 0.1 | Balance | 3 |
| | peroxide | | fluoride | | | | | | | |
| Example 7 | Hydrogen | 2 | Hydrogen | 0.1 | A2 | 0.03 | E40 | 0.1 | Balance | 3 |
| | peroxide | | fluoride | | | | | | | |
| Example 8 | Hydrogen | 2 | Hydrogen | 0.1 | A3 | 0.03 | E40 | 0.1 | Balance | 3 |
| | peroxide | | fluoride | | | | | | | |
| Example 9 | Hydrogen | 2 | Hydrogen | 0.1 | A4 | 0.03 | E40 | 0.1 | Balance | 3 |
| | peroxide | | fluoride | | | | | | | |
| Example 10 | Hydrogen | 2 | Hydrogen | 0.1 | Lupasol | 0.05 | E40 | 0.1 | Balance | 3 |
| | peroxide | | fluoride | | PR8515 | | | | | |

TABLE 2

| | | | Etching selectivity | |
|---|---|---|---|---|
| | ER (Å/min) | | SiGe₄₀/ | |
| | SiGe₄₀ | SiGe₂₀ | SiGe₂₀ | Evaluation |
| Comparative Example 1 | 17 | 2.6 | 7 | B |
| Comparative Example 2 | 98 | 4.6 | 21 | B |
| Comparative Example 3 | 19 | 3.4 | 6 | B |
| Example 1 | 108 | 1.9 | 57 | A |
| Comparative Example 4 | 50 | 4 | 13 | B |
| Comparative Example 5 | 25 | 1.9 | 13 | B |
| Comparative Example 6 | 43 | 3.2 | 13 | B |
| Example 2 | 96 | 2.4 | 40 | A |
| Example 3 | 169 | 3.2 | 53 | A |
| Example 4 | 91 | 2.1 | 43 | A |
| Example 5 | 117 | 2.6 | 45 | A |
| Example 6 | 62 | 1.8 | 34 | A |
| Example 7 | 121 | 1.2 | 101 | A |
| Example 8 | 160 | 1.1 | 145 | A |
| Example 9 | 184 | 1.8 | 102 | A |
| Example 10 | 237 | 2.4 | 99 | A |

TABLE 3

| | Oxidizing agent | | Fluorine-based compound | | Amine compound | | Corrosion inhibitor | | | |
|---|---|---|---|---|---|---|---|---|---|---|
| | | Content | | Content | | Content | | Content | Solvent | |
| | Kind | (mass %) | Kind | (mass %) | Kind | (mass %) | Kind | (mass %) | Water | pH |
| Example 11 | Hydrogen | 2 | Hydrogen | 0.1 | EPOMIN | 0.03 | E40 | 0.1 | Balance | 3 |
| | peroxide | | fluoride | | SP-003 | | | | | |
| Example 12 | Hydrogen | 2 | Hydrogen | 0.1 | EPOMIN | 0.03 | E40 | 0.1 | Balance | 3 |
| | peroxide | | fluoride | | SP-006 | | | | | |
| Example 13 | Hydrogen | 2 | Hydrogen | 0.1 | EPOMIN | 0.03 | E40 | 0.1 | Balance | 3 |
| | peroxide | | fluoride | | SP-012 | | | | | |
| Example 14 | Hydrogen | 2 | Hydrogen | 0.1 | EPOMIN | 0.03 | E40 | 0.1 | Balance | 3 |
| | peroxide | | fluoride | | SP-018 | | | | | |
| Example 15 | Hydrogen | 2 | Hydrogen | 0.1 | EDA | 0.08 | E40 | 0.1 | Balance | 4 |
| | peroxide | | fluoride | | | | | | | |
| Example 16 | Hydrogen | 2 | Hydrogen | 0.1 | EDA | 0.08 | E100 | 0.5 | Balance | 4 |
| | peroxide | | fluoride | | | | | | | |
| Example 17 | Hydrogen | 2 | Hydrogen | 0.1 | EDA | 0.08 | E100 | 0.1 | Balance | 4 |
| | peroxide | | fluoride | | | | | | | |
| Example 18 | Hydrogen | 2 | Hydrogen | 0.1 | EDA | 0.08 | TMN6 | 0.01 | Balance | 4 |
| | peroxide | | fluoride | | | | | | | |
| Example 19 | Hydrogen | 2 | Hydrogen | 0.1 | EDA | 0.08 | TMN10 | 0.01 | Balance | 4 |
| | peroxide | | fluoride | | | | | | | |
| Example 20 | Hydrogen | 2 | Hydrogen | 0.1 | EDA | 0.08 | Softanol | 0.001 | Balance | 4 |
| | peroxide | | fluoride | | | | 90 | | | |
| Example 21 | Hydrogen | 2 | Hydrogen | 0.1 | EDA | 0.08 | Triton | 0.0003 | Balance | 4 |
| | peroxide | | fluoride | | | | X-100 | | | |

TABLE 4

| | | | Etching selectivity | |
|---|---|---|---|---|
| | ER (Å/min) | | SiGe₄₀/ | |
| | SiGe₄₀ | SiGe₂₀ | SiGe₂₀ | Evaluation |
| Example 11 | 218 | 1.8 | 121 | A |
| Example 12 | 225 | 1.7 | 132 | A |
| Example 13 | 229 | 1.6 | 143 | A |
| Example 14 | 233 | 1.6 | 146 | A |
| Example 15 | 108 | 1.8 | 60 | A |
| Example 16 | 101 | 1.8 | 56 | A |
| Example 17 | 105 | 2.0 | 53 | A |
| Example 18 | 120 | 1.6 | 75 | A |
| Example 19 | 123 | 1.6 | 77 | A |
| Example 20 | 119 | 1.4 | 85 | A |
| Example 21 | 115 | 1.6 | 72 | A |

TABLE 5

| | | | | | | | Corrosion | | Corrosion | | | |
|---|---|---|---|---|---|---|---|---|---|---|---|---|
| | Oxidizing agent | | Fluorine-based compound | | Amine compound | | inhibitor 1 | | inhibitor 2 | | | |
| | | Content | | Content | | Content | | Content | | Content | Solvent | |
| | Kind | (mass %) | Kind | (mass %) | Kind | (mass %) | Kind | (mass %) | Kind | (mass %) | Water | pH |
| Example 22 | Hydrogen | 2 | Hydrogen | 0.1 | EDA | 0.08 | E40 | 0.1 | Softanol | 0.001 | Balance | 4 |
| | peroxide | | fluoride | | | | | | 90 | | | |
| Example 23 | Hydrogen | 2 | Hydrogen | 0.1 | EDA | 0.08 | E40 | 0.1 | TMN10 | 0.01 | Balance | 4 |
| | peroxide | | fluoride | | | | | | | | | |
| Example 24 | Hydrogen | 2 | Hydrogen | 0.1 | EDA | 0.08 | E40 | 0.1 | TMN6 | 0.01 | Balance | 4 |
| | peroxide | | fluoride | | | | | | | | | |
| Example 25 | Hydrogen | 2 | Hydrogen | 0.1 | EDA | 0.05 | DBSA | 0.0005 | — | — | Balance | 3 |
| | peroxide | | fluoride | | | | | | | | | |
| Example 26 | Hydrogen | 2 | Hydrogen | 0.1 | EDA | 0.05 | E40 | 0.1 | — | — | Balance | 3 |
| | peroxide | | fluoride | | | | | | | | | |
| Example 27 | Hydrogen | 2 | Hydrogen | 0.1 | EDA | 0.1 | E40 | 0.1 | — | — | Balance | 4 |
| | peroxide | | fluoride | | | | | | | | | |
| Example 28 | Hydrogen | 2 | Hydrogen | 6 | EDA | 5 | E40 | 0.1 | — | — | Balance | 4 |
| | peroxide | | fluoride | | | | | | | | | |
| Example 29 | Hydrogen | 2 | Hydrogen | 4 | EDA | 3.3 | E40 | 0.1 | — | — | Balance | 4 |
| | peroxide | | fluoride | | | | | | | | | |
| Example 30 | Hydrogen | 2 | Hydrogen | 2 | EDA | 1.7 | E40 | 0.1 | — | — | Balance | 4 |
| | peroxide | | fluoride | | | | | | | | | |
| Example 31 | Hydrogen | 2 | Hydrogen | 1 | EDA | 0.8 | TERGITOL | 0.008 | — | — | Balance | 4 |
| | peroxide | | fluoride | | | | TMN-10 | | | | | |
| Example 32 | Hydrogen | 2 | Hydrogen | 0.1 | Lupasol | 0.001 | E40 | 0.1 | — | — | Balance | 3 |
| | peroxide | | fluoride | | PR8515 | | | | | | | |
| Example 33 | Hydrogen | 2 | Hydrogen | 0.1 | Lupasol | 0.01 | E40 | 0.1 | — | — | Balance | 3 |
| | peroxide | | fluoride | | PR8515 | | | | | | | |
| Example 34 | Hydrogen | 2 | Hydrogen | 0.1 | Lupasol | 0.2 | E40 | 0.1 | — | — | Balance | 3 |
| | peroxide | | fluoride | | PR8515 | | | | | | | |
| Example 35 | Hydrogen | 2 | Hydrogen | 0.08 | EDA | 0.08 | E40 | 0.1 | — | — | Balance | 4 |
| | peroxide | | fluoride | | | | | | | | | |
| Example 36 | Hydrogen | 1.2 | Hydrogen | 0.05 | EDA | 0.04 | E40 | 0.1 | — | — | Balance | 3 |
| | peroxide | | fluoride | | | | | | | | | |

TABLE 6

| | | | Etching selectivity | |
|---|---|---|---|---|
| | ER (Å/min) | | SiGe₄₀/ | |
| | SiGe₄₀ | SiGe₂₀ | SiGe₂₀ | Evaluation |
| Example 22 | 89 | 1.1 | 81 | A |
| Example 23 | 95 | 0.7 | 146 | A |
| Example 24 | 93 | 0.8 | 110 | A |
| Example 25 | 97 | 1.2 | 80 | A |
| Example 26 | 98 | 1.4 | 69 | A |
| Example 27 | 110 | 1.5 | 73 | A |
| Example 28 | 42 | 1 | 42 | A |
| Example 29 | 74 | 0.7 | 106 | A |
| Example 30 | 116 | 1.2 | 97 | A |
| Example 31 | 120 | 1.1 | 109 | A |
| Example 32 | 122 | 1.6 | 76 | A |
| Example 33 | 236 | 1.4 | 169 | A |
| Example 34 | 320 | 5.2 | 62 | A |
| Example 35 | 102 | 2.1 | 49 | A |
| Example 36 | 52 | 1.6 | 33 | A |

TABLE 7

| | Oxidizing agent | | Fluorine-based compound | | Amine compound | |
|---|---|---|---|---|---|---|
| | | Content | | Content | | Content |
| | Kind | (mass %) | Kind | (mass %) | Kind | (mass %) |
| Example 37 | Hydrogen peroxide | 0.2 | Hydrogen fluoride | 0.1 | Lupasol | 0.05 |
| | | | | | PR8515 | |
| Example 38 | Hydrogen peroxide | 0.5 | Hydrogen fluoride | 0.1 | Lupasol | 0.05 |
| | | | | | PR8515 | |
| Example 39 | Hydrogen peroxide | 1 | Hydrogen fluoride | 0.1 | EDA | 0.08 |
| Example 40 | Hydrogen peroxide | 3 | Hydrogen fluoride | 0.1 | EDA | 0.08 |
| Example 41 | Hydrogen peroxide | 4 | Hydrogen fluoride | 0.1 | EDA | 0.08 |
| Example 42 | Hydrogen peroxide | 6 | Hydrogen fluoride | 0.1 | EDA | 0.08 |
| Example 43 | Hydrogen peroxide | 8 | Hydrogen fluoride | 0.1 | EDA | 0.08 |
| Example 44 | Hydrogen peroxide | 10 | Hydrogen fluoride | 0.1 | EDA | 0.08 |
| Example 45 | Iodic acid | 0.3 | Hydrogen fluoride | 0.1 | EDA | 0.05 |
| Example 46 | Iodic acid | 0.1 | Hydrogen fluoride | 0.1 | EDA | 0.05 |
| Example 47 | Hydrogen peroxide | 5 | Tetramethylammonium | 0.8 | EDA | 0.08 |
| | | | fluoride | | | |

| | |
|---|---|
| Corrosion inhibitor 1 | Corrosion inhibitor 2 |

| | | Content | | Content | Solvent | |
|---|---|---|---|---|---|---|
| | Kind | (mass %) | Kind | (mass %) | Water | pH |
| Example 37 | E40 | 0.1 | — | — | Balance | 3 |
| Example 38 | E40 | 0.1 | — | — | Balance | 3 |
| Example 39 | E40 | 0.1 | — | — | Balance | 4 |
| Example 40 | E40 | 0.1 | — | — | Balance | 4 |
| Example 41 | E40 | 0.1 | — | — | Balance | 4 |
| Example 42 | TMN6 | 0.02 | — | — | Balance | 4 |
| Example 43 | TMN6 | 0.02 | — | — | Balance | 4 |
| Example 44 | TMN6 | 0.02 | — | — | Balance | 4 |
| Example 45 | E40 | 0.1 | — | — | Balance | 3 |
| Example 46 | E40 | 0.1 | — | — | Balance | 3 |
| Example 47 | TERGITOL | 0.008 | Sulfuric acid | 0.2 | Balance | 4 |
| | TMN-10 | | | | | |

TABLE 8

| | | | Etching selectivity | |
|---|---|---|---|---|
| | ER (Å/min) | | SiGe₄₀/ | |
| | SiGe₄₀ | SiGe₂₀ | SiGe₂₀ | Evaluation |
| Example 37 | 22 | 0.2 | 110 | A |
| Example 38 | 62 | 0.6 | 103 | A |
| Example 39 | 65 | 0.8 | 83 | A |
| Example 40 | 159 | 2.9 | 55 | A |
| Example 41 | 189 | 4.0 | 47 | A |
| Example 42 | 201 | 2.1 | 97 | A |
| Example 43 | 204 | 2.8 | 73 | A |
| Example 44 | 206 | 3.5 | 59 | A |
| Example 45 | 130 | 3.1 | 42 | A |
| Example 46 | 67 | 1.1 | 61 | A |
| Example 47 | 144 | 3.2 | 45 | A |

From the above, it was at least confirmed that the Examples exhibited excellent selectivity for SiGe.

### 2. Test 2

Further, the additive effect when imparting corrosion resistance to SiOₓ was also examined. Unless otherwise specified, the measurement items and evaluation items common to Test 1 (e.g., the etching rate of SiGe₄₀, the etching rate of SiGe₂₀, and the selectivity of SiGe₄₀ to SiGe₂₀ (SiGe₄₀/SiGe₂₀)) were performed under the same conditions as in Test 1.

### <Measurement of Etching Rate>

Test samples (wafer coupons) were obtained by cutting, in plain view, a laminate (blanket wafer) on which an SiOₓ layer (film thickness: 200 nm) was formed into pieces of 2 cm×2 cm. Thereafter, 100 mL of each etching solution of each of the Examples and Comparative Examples was placed in a 200-mL cup. Each sample was then introduced into the cup and treated by stirring at 300 rpm at a treatment temperature of 25° C. Note that the treatment time was 3 minutes for the laminate including the SiOₓ layer. After the treatment, each sample was taken out of the etching solution, washed with water at room temperature for 30 seconds, and dried by nitrogen blow.

Then, for SiOₓ, the film reduction after the treatment was evaluated by measuring the etching rate (ER, Å/min) after the treatment relative to that before the treatment. A lower etching rate of the SiOₓ layer indicates that damage to the SiOₓ layer was more effectively suppressed. Note that the film thickness before the treatment and the film thickness after the treatment were measured by the following methods.
The film thickness of SiOₓ was measured using an ellipsometer (“L115S300 STOKES WAFERSKAN”, manufactured by Gaertner Scientific Corporation).

### <Evaluation of Selectivity>

The selectivity of SiGe₄₀ to SiOₓ (SiGe₄₀/SiOₓ) was determined by dividing the etching rate of SiGe₄₀ by the etching rate of SiOₓ. A larger value indicates better selectivity. The selectivity was evaluated according to the following criteria.
A: The selectivity value was 100 or more.
B: The selectivity value was less than 100.

### <Evaluation of Defoaming Properties>

In a 50-mL graduated cylinder, 25 mL of each etching solution of each of the Examples was placed, and shaking by hand was performed for 30 seconds. The shaking was performed under identical conditions among all the Examples and Comparative Examples. After the shaking, the time required for the foam to disappear was measured, and a shorter time was regarded as indicating better defoaming properties. The defoaming properties were evaluated according to the following criteria.
A: The foam disappeared in less than 5 minutes.
B: The foam disappeared in 5 minutes or more.

As a result, the evaluation was “A” in all of the Examples.

Table 9 shows the compositions and pH values of the etching solutions of Examples 48 to 54, and Table 10 shows the evaluation results thereof.

TABLE 9

| | | | Fluorine-based | | Amine | | Corrosion | | Corrosion | | | |
|---|---|---|---|---|---|---|---|---|---|---|---|---|
| | Oxidizing agent | | compound | | compound | | inhibitor 1 | | inhibitor 3 | | | |
| | | Content | | Content | | Content | | Content | | Content | Solvent | |
| | Kind | (mass %) | Kind | (mass %) | Kind | (mass %) | Kind | (mass %) | Kind | (mass %) | Water | pH |
| Example 48 | Hydrogen | 2 | Hydrogen | 0.1 | EDA | 0.08 | E40 | 0.1 | PVP | 0.1 | Balance | 4 |
| | peroxide | | fluoride | | | | | | | | | |
| Example 49 | Hydrogen | 2 | Hydrogen | 0.1 | EDA | 0.08 | E40 | 0.1 | PVP | 0.05 | Balance | 4 |
| | peroxide | | fluoride | | | | | | | | | |
| Example 50 | Hydrogen | 2 | Hydrogen | 0.1 | EDA | 0.08 | E40 | 0.1 | PVP | 0.01 | Balance | 4 |
| | peroxide | | fluoride | | | | | | | | | |
| Example 51 | Hydrogen | 2 | Hydrogen | 0.1 | EDA | 0.08 | E40 | 0.1 | PVP | 0.001 | Balance | 4 |
| | peroxide | | fluoride | | | | | | | | | |
| Example 52 | Hydrogen | 2 | Hydrogen | 0.1 | EDA | 0.08 | E40 | 0.1 | PVP | 0.0005 | Balance | 4 |
| | peroxide | | fluoride | | | | | | | | | |
| Example 53 | Hydrogen | 2 | Hydrogen | 0.1 | EDA | 0.08 | E40 | 0.1 | PVP | 0.0002 | Balance | 4 |
| | peroxide | | fuoride | | | | | | | | | |
| Example 54 | Hydrogen | 2 | Hydrogen | 0.1 | EDA | 0.08 | E40 | 0.1 | PVP | 0.0001 | Balance | 4 |
| | peroxide | | fluoride | | | | | | | | | |

TABLE 10

| | | | Etching selectivity | | | | Etching selectivity | |
|---|---|---|---|---|---|---|---|---|
| | ER (Å/min) | | SiGe₄₀/ | | ER (Å/min) | | SiGe₄₀/ | |
| | SiGe₄₀ | SiGe₂₀ | SiGe₂₀ | Evaluation | SiGe₄₀ | SiOx | SiOx | Evaluation |
| Example 48 | 89 | 2.1 | 42 | A | 89 | <0.1 | >100 | A |
| Example 49 | 95 | 2.0 | 49 | A | 95 | <0.1 | >100 | A |
| Example 50 | 97 | 1.8 | 55 | A | 97 | <0.1 | >100 | A |
| Example 51 | 100 | 1.6 | 61 | A | 100 | <0.1 | >100 | A |
| Example 52 | 103 | 1.6 | 63 | A | 103 | <0.1 | >100 | A |
| Example 53 | 104 | 1.7 | 62 | A | 104 | <0.1 | >100 | A |
| Example 54 | 106 | 1.8 | 60 | A | 106 | 0.9 | 118 | A |

### 3. Test 3

Unless otherwise specified, the measurement items and evaluation items common to Test 1 (e.g., the etching rate of SiGe₄₀, the etching rate of SiGe₂₀, and the selectivity of SiGe₄₀ to SiGe₂₀ (SiGe₄₀/SiGe₂₀)) were performed under the same conditions as in Test 1.

### <Measurement of Etching Rate>

Test samples (wafer coupons) were obtained by cutting, in plain view, a laminate (blanket wafer) on which an SiOₓ layer (film thickness: 200 nm) was formed into pieces of 2 cm 2 cm. Thereafter, 100 mL of each etching solution of each of the Examples was placed in a 200-mL cup. Each sample was then introduced into the cup and treated by stirring at 300 rpm at a treatment temperature of 25° C. Note that the treatment time was 3 minutes for the laminate including the SiOₓ layer. After the treatment, each sample was taken out of the etching solution, washed with water at room temperature for 30 seconds, and dried by nitrogen blow.

### <Evaluation of Defoaming Properties>

In a 50-mL graduated cylinder, 25 mL of each etching solution of each of the Examples was placed, and shaking by hand was performed for 30 seconds. The shaking was performed under identical conditions among all the Examples. After the shaking, the time required for the foam to disappear was measured, and a shorter time was regarded as indicating better defoaming properties. The defoaming properties were evaluated according to the following criteria.
A: The foam disappeared in less than 5 minutes.
B: The foam disappeared in 5 minutes or more.

As a result, the evaluation was “A” in all of the Examples.

Table 11 shows the compositions and pH values of the etching solutions of Examples 55 to 59, and Table 12 shows the evaluation results thereof.

TABLE 11

| | Oxidizing agent | | Fluorine-based compound | | Diamine compound | | Corrosion inhibitor | | | |
|---|---|---|---|---|---|---|---|---|---|---|
| | | Content | | Content | | Content | | Content | Solvent | |
| | Kind | (mass %) | Kind | (mass %) | Kind | (mass %) | Kind | (mass %) | Water | pH |
| Example 55 | Hydrogen | 2 | Hydrogen | 0.5 | EDA | 0.001 | E40 | 0.01 | Balance | 3 |
| | peroxide | | fluoride | | | | | | | |
| Example 56 | Hydrogen | 2 | Hydrogen | 0.5 | DETA | 0.001 | E40 | 0.01 | Balance | 3 |
| | peroxide | | fluoride | | | | | | | |
| Example 57 | Hydrogen | 2 | Hydrogen | 0.1 | EDA | 0.01 | E40 | 0.01 | Balance | 3 |
| | peroxide | | fluoride | | | | | | | |
| Example 58 | Hydrogen | 2 | Hydrogen | 1 | EDA | 0.1 | E40 | 0.01 | Balance | 3 |
| | peroxide | | fluoride | | | | | | | |
| Example 59 | Hydrogen | 2 | Hydrogen | 0.3 | EDA | 0.03 | E40 | 0.005 | Balance | 3 |
| | peroxide | | fluoride | | | | | | | |

TABLE 12

| | | | Etching selectivity | |
|---|---|---|---|---|
| | ER (Å/min) | | SiGe₄₀/ | |
| | SiGe₄₀ | SiGe₂₀ | SiGe₂₀ | Evaluation |
| Example 53 | 5.3 | 0.1 | 51 | A |
| Example 56 | 4.9 | 0.1 | 49 | A |
| Example 57 | 4.3 | 0.1 | 43 | A |
| Example 58 | 5.7 | 0.1 | 57 | A |
| Example 59 | 5.4 | 0.1 | 54 | A |

From the above, it was at least confirmed that, according to the Examples, not only excellent selectivity for SiGe was achieved, but also the selectivity of silicon oxide relative to SiGe was improved.

1. An etching composition comprising:
(A) an oxidizing agent;
(B) a compound capable of releasing fluoride ions or a salt thereof;
(C) at least one amine compound selected from the group consisting of an amine compound (c1) represented by the following General Formula (c1), an amine compound (c2) represented by the following General Formula (c2), and an amine compound (c3) represented by the following General Formula (c3), piperazine, 1,5,9-triazacyclododecane, 1,4,7-triazacyclononane, cyclen, cyclam, tetraethylenepentamine, and polyethyleneimine, and derivatives thereof; and
(D) a corrosion inhibitor: 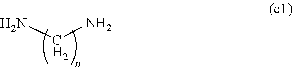
in General Formula (c1), n represents a number of 1 or more, 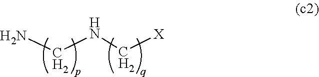
in General Formula (c2), X represents an NH₂ group, an OH group, or an alkyl group, p and q represent numbers of 1 or more, and p and q may be the same or different, and 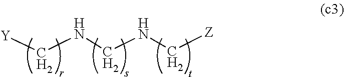
in General Formula (c3), Y and Z each independently represent an NH₂ group, an OH group, or an alkyl group, r, s, and t represent numbers of 1 or more, and r, s, and t may be the same or different.

2. The etching composition according to claim 1, wherein
the component (A) includes at least one selected from the group consisting of hydrogen peroxide and an oxo acid.

3. The etching composition according to claim 1, wherein
the component (B) is at least one selected from the group consisting of hydrogen fluoride, ammonium fluoride, ammonium hydrogen fluoride, triethanolammonium fluoride, diglycolammonium fluoride, methyldiethanolammonium fluoride, tetramethylammonium fluoride, triethylamine trihydrofluoride, fluoroboric acid, tetrafluoroboric acid, ammonium tetrafluoroborate, fluoroacetic acid, ammonium fluoroacetate, trifluoroacetic acid, fluorosilicic acid, ammonium fluorosilicate, and tetrabutylammonium tetrafluoroborate.

4. The etching composition according to claim 1, wherein
a content of the component (A) is 0.01 to 20 mass %.

5. The etching composition according to claim 1, wherein
a content of the component (B) is 0.01 to 10 mass %.

6. The etching composition according to claim 1, wherein
a content of the component (C) is 0.0005 to 10 mass %.

7. The etching composition according to claim 1, further comprising water.

8. The etching composition according to claim 7, wherein
the etching composition has a pH of 6 or less.

9. The etching composition according to claim 1, wherein
the component (D) is at least one selected from the group consisting of a nonionic surfactant, an anionic surfactant, and a cationic surfactant.

10. The etching composition according to claim 1, wherein
the etching composition is an etching composition for selectively etching a layer containing a silicon germanium alloy (SiGe).

11. An etching method comprising etching a laminated substrate including a substrate and a layer provided on the substrate and comprising a silicon germanium alloy (SiGe) using an etching composition,
wherein the etching composition comprises:
(A) an oxidizing agent;
(B) a compound capable of releasing fluoride ions or a salt thereof;
(C) at least one amine compound selected from the group consisting of an amine compound (c1) represented by the following General Formula (c1), an amine compound (c2) represented by the following General Formula (c2), and an amine compound (c3) represented by the following General Formula (c3), piperazine, 1,5,9-triazacyclododecane, 1,4,7-triazacyclononane, cyclen, cyclam, tetraethylenepentamine, and polyethyleneimine, and derivatives thereof; and
(D) a corrosion inhibitor: 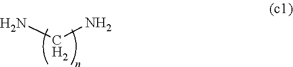
in General Formula (c1), n represents a number of 1 or more, 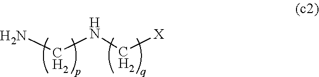
in General Formula (c2), X represents an NH₂ group, an OH group, or an alkyl group, p and q represent numbers of 1 or more, and p and q may be the same or different, and 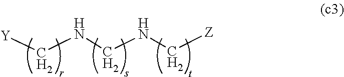
in General Formula (c3), Y and Z each independently represent an NH₂ group, an OH group, or an alkyl group, r, s, and t represent numbers of 1 or more, and r, s, and t may be the same or different.

12. A method for manufacturing a semiconductor substrate, the method comprising:
etching a laminated substrate including a substrate and a layer provided on the substrate and comprising a silicon germanium alloy (SiGe) using an etching composition; and
cleaning the etched laminated substrate with a cleaning solution,
wherein the etching composition comprises:
(A) an oxidizing agent;
(B) a compound capable of releasing fluoride ions or a salt thereof;
(C) at least one amine compound selected from the group consisting of an amine compound (c1) represented by the following General Formula (c1), an amine compound (c2) represented by the following General Formula (c2), and an amine compound (c3) represented by the following General Formula (c3), piperazine, 1,5,9-triazacyclododecane, 1,4,7-triazacyclononane, cyclen, cyclam, tetraethylenepentamine, and polyethyleneimine, and derivatives thereof; and
(D) a corrosion inhibitor: 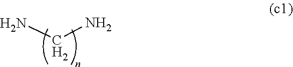
in General Formula (c1), n represents a number of 1 or more, 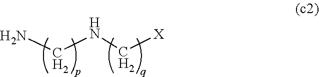
in General Formula (c2), X represents an NH₂ group, an OH group, or an alkyl group, p and q represent numbers of 1 or more, and p and q may be the same or different, and 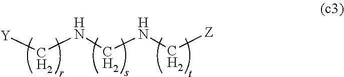
in General Formula (c3), Y and Z each independently represent an NH₂ group, an OH group, or an alkyl group, r, s, and t represent numbers of 1 or more, and r, s, and t may be the same or different.
